(19) United States
(12) Patent Application Publication
(10) Pub. No.: US 2007/0203594 A1
(43) Pub. Date: Aug. 30, 2007

(54) Stereo security face plate assembly and method

(75) Inventor: Gunnar Hovden, Los Gatos, CA (US)

Correspondence Address: Trellis Intellectual Property Law Group, PC, 1900 EMBARCADERO ROAD, SUITE 109, PALO ALTO, CA, 94303, US

(73) Assignees: Sony Corporation, Tokyo (JP); Sony Electronics Inc., Park Ridge, NJ (US)

(21) Appl. No.: 11/365,060

(22) Filed: Feb. 28, 2006

(51) Int. Cl. G06F 17/00; H04B 1/00; H05K 11/02

(52) U.S. Cl. 700/94; 381/86; 455/345

(57) ABSTRACT

A method for listening to music comprising recording music by a car security face plate assembly coupled to a car stereo system, removing the car security face plate assembly from the car stereo system, and listening to music which was recorded by the car security face plate assembly. A method for recording music comprising providing a car security face plate assembly having a digital audio assembly, engaging the car security face plate assembly to a car stereo system, and recording music after engaging the car security face plate assembly to the car stereo system. A security face plate assembly for a car stereo comprising a security face plate having a digital audio assembly.

### FIELD OF THE INVENTION

Embodiments of the present invention are related to a digital audio assembly (e.g., an MP3 assembly) and method. More specifically, embodiments of the present invention provide a car-stereo security face plate assembly and method for listening to music.

### BACKGROUND OF THE INVENTION

MP3 is the name of the file extension and also the name of the type of file for MPEG, audio layer 3. Layer 3 is one of three coding schemes (layer 1, layer 2 and layer 3) for the compression of audio signals. Layer 3 uses perceptual audio coding and psychoacoustic compression to remove all superfluous information, more specifically, the redundant and irrelevant parts of a sound signal which the human ear would not typically hear. It also adds a MDCT (Modified Discrete Cosine Transform) that implements a filter bank, increasing the frequency resolution 18 times higher than that of layer 2. The result in real terms is layer 3 shrinks the original sound data from a CD (with a bit rate of 1411.2 kilobits per one second of stereo music) by a factor of 12 (down to 112-128 kbps) with a minor degradation in sound quality.

MP3 (MPEG-1 Audio Layer-3) is a standard technology and format for compressing a sound sequence into a very small file (about one-twelfth the size of the original file) without preserving the original level of sound quality when it is played. MP3 files (identified with the file name suffix of “.mp3”) are available for downloading from a number of Web sites. Many Windows 98 users find that they have a player built into their operating system. Otherwise, one may download a player from one of several popular MP3 sites. MP3 files are usually download-and-play files rather than streaming sound files that one link-and-listen-to with RealPlayer and similar products. However, streaming MP3 is possible.

An MP-3 player comprises software that allows the user to listen to music or sound in MP3 format. Winamp (PC), MacAmp (Mac), and mpeg123 (UNIX) are popular MP3 players, but there are many others. To create an MP3 file, one may employ a program called a ripper to obtain a selection from a CD onto a hard disk and another program called an encoder to convert the selection to an MP3 file. Most people, however, simply download MP3s from someone else and play them.

Currently there are two conventional methods for playing the same MP3 files in a portable player (e.g., Apple iPod, Sony NW-HD3) and in a car stereo. For one method, the car stereo has a digital or analog input where the portable MP3 player can be connected via a cable or cord. A cord is inconvenient and cumbersome. There is no dedicated space for the portable MP3 player; hence, it will float around the car, frequently falling down on the floor and dangerously distracting the driver of the car.

In another method, the car stereo accepts a memory card (e.g., memory sticks, flash memory, etc) of the same type that is employed in the portable player. This method presents a number of problems. First, it is a hassle to turn off the portable unit, take out the memory card, insert the memory card in the car stereo, and subsequently turn on the car stereo. Second, when a memory card is inserted in the car stereo, information about which music being played is lost and the user will have to search for the particular music he/she was listening. Lastly, there will be a break in the music while transferring the memory card from the portable unit to the car stereo. Many users find it unacceptable to be without music, even for very short period of time.

It is well known that many car stereos have a detachable faceplate as a theft protection. Commercial available face plates are available on products sold by Blaupunkt Corporation, such as the following: Indianapolis 34, Monte Carlo MP34, and Montreal CD34. These products are available on line at http://www.midwestelectronics.com. The owner would remove the face plate from the car stereo and bring it with him/her when leaving the car. The car stereo is useless without the face plate.

### SUMMARY OF EMBODIMENTS OF THE INVENTION

Embodiments of the present invention provide a method for listening to music comprising recording music by a car security face plate assembly coupled to a car stereo system, removing the car security face plate assembly from the car stereo system, and listening to music which was recorded by the car security face plate assembly. The car security face plate assembly includes a digital audio assembly (e.g., an MP3 player/recorder) for recording and playing the music. The music may be listened to by ear phones or by a speaker contained within the car security face plate assembly. The car security face plate assembly may include a power supply, such as a battery which may be charged by the car battery when the car security plate assembly is coupled to the car stereo system. When the car security face plate assembly is decoupled from the car stereo system, the decoupled car security face plate assembly provides a theft protection for the car stereo system and a music player for music which was recorded by the digital audio assembly.

Embodiments of the present invention also provide a method for recording music comprising providing a car security face plate assembly having a digital audio assembly, engaging the car security face plate assembly to a car stereo system, and recording music after engaging the car security face plate assembly to the car stereo system. The recording of music may be by the car security face plate assembly from the car stereo system, or by the car stereo system from the car security face plate assembly.

Embodiments of the present invention further also provide a security face plate assembly for a car stereo. The security face plate assembly includes a security face plate having a digital audio assembly. The digital audio assembly may be an MP3 player/recorder having a power supply (e.g., a battery), a processor (e.g., a CPU), a memory for storing music, a converter, and an input/output section.

Embodiments of the present invention further also provide a security face plate assembly comprising a security face plate having a means for processing digital audio signals. The means for processing digital audio signals may comprise a player or a recorder of digital audio signals. The means for processing digital audio signals may be selected from a group of audio formats consisting of MP2, MP3, MPC, APE, FLAC, AIFF, WAV and OGG.

Embodiments of the present invention further also provide a method for recording and listening to music. The method comprises providing a car security face plate assembly having a digital audio assembly, engaging the car security face plate assembly to a computer system, recording music from the computer system, and listening to the music which was recorded by the car security face plate assembly from the computer system. The listening to the music may include engaging the car security face plate assembly to a car stereo system, and listening to the music with the car stereo system.

These provisions, together with the various ancillary provisions and features which will become apparent to those skilled in the art as the following description proceeds, are attained by the methods and assemblies of the present invention.

### BRIEF DESCRIPTION OF THE DRAWINGS

FIG. 1 illustrates a prior art car stereo-MP3 assembly having an MP3 player engaged to a car stereo through a linkage assembly;

FIG. 2 illustrates a side elevational view of an embodiment of the security face plate assembly of the present invention coupled to a car stereo system;

FIG. 3 is a side elevational view of an embodiment of the security face plate assembly of the present invention removed from the car stereo system;

FIG. 4 is a front elevational view of an embodiment of the security face plate assembly having control knobs for activating and controlling the car stereo system when engaged to the car stereo system, and having a set of ear phones coupled thereto for hearing music produced by the built-in an MP3 player/recorder;

FIG. 5 is a schematic diagram of an embodiment of the MP3 player/recorder which is built into the security face plate assembly;

FIG. 6 is an elevational view of the security face plate assembly showing exemplary control bottoms for controlling and/or operating the car stereo and the MP3 player/recorder; and

FIG. 7 is a schematic view of a computer assembly to which the security face plate assembly may be coupled for downloading and recording music

### DETAILED DESCRIPTION OF THE EMBODIMENTS OF THE INVENTION

In the description herein, numerous specific details are provided, such as examples of components and/or methods, to provide a thorough understanding of the embodiments of the present invention. One skilled in the relevant art will recognize, however, that an embodiment of the invention may be practiced without one or more of the specific details, or with other apparatus, systems, assemblies, methods, components, materials, parts, and/or the like. In other instances, well-known structures, materials, or operations are not specifically shown or described in detail to avoid obscuring aspects of the embodiments of the present invention.

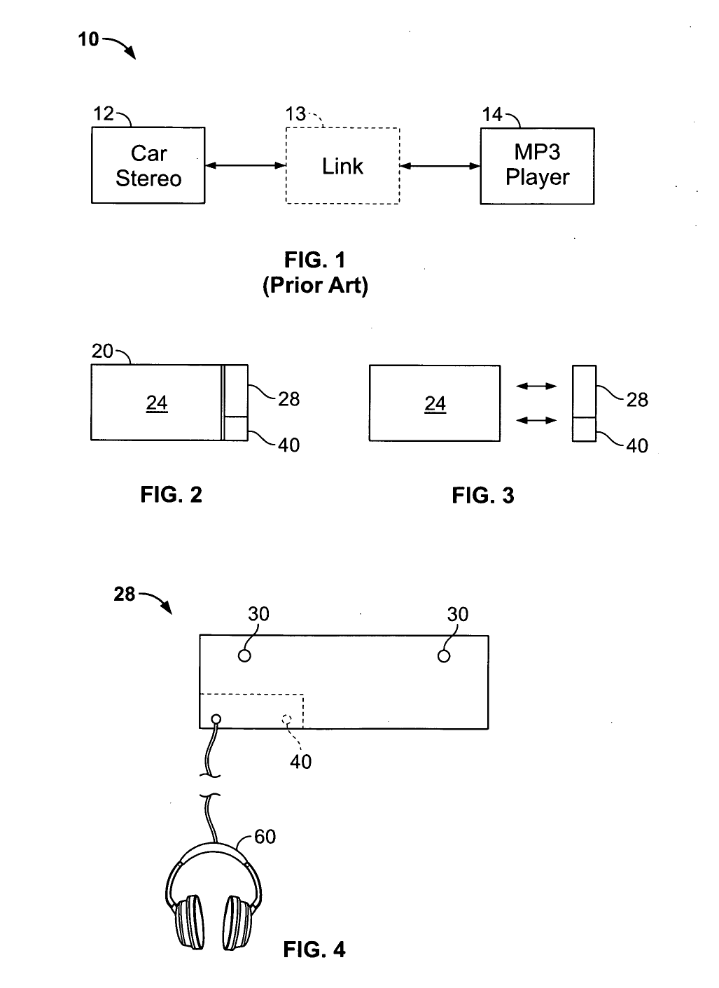

Referring in detail now to the drawings, there is seen in FIG. 1 a prior art car stereo-MP3 assembly, generally illustrated as 10. The car stereo-MP3 assembly 10 includes a car stereo 12 coupled to an MP3 player 14 through a linkage assembly 13. The MP3 player 14 does not directly engage the car stereo 12. The linkage assembly 13 has one or more cables/lines for electrically engaging the MP3 player 14 to the car stereo 12. When ever “car” is mentioned herein, it is to be understood to mean any type of vehicle, such as a boat, a truck, or any other machine or device having a stereo system that remains in place after the owner leaves the machine or device.

Referring now to FIGS. 2-7 for various embodiments of the present invention, there is seen a car-stereo security face plate assembly, generally illustrated as 20 in FIG. 2. The car-stereo security face plate assembly 20 includes a car stereo system 24 and a security face plate assembly 28 having a built-in digital audio assembly, such as MP3 player/recorder 40. While embodiments of the present invention are described with respect to digital audio signals comprising an MP3 format, it is to be understood that the spirit and scope of the present invention includes digital audio signals in any other suitable audio format, such as by way of illustration only, MP2, MPC, APE, FLAC, AIFF, WAV and OGG, etc. Thus, when digital audio signals are to be processed (e.g., played or recorded), the processing of digital audio signals may be selected from a group of audio formats consisting of MP2, MP3, MPC, APE, FLAC, AIFF, WAV and OGG, and etc.

As shown in FIG. 3, the security face plate assembly 28 may be readily detached or removed from the car stereo system 24 for security purposes when a user leaves the car. When the user returns to the car, the security face plate assembly 28 may be coupled back into place against the car stereo system 24 so the user may listen to music.

As shown in FIG. 4 the security face plate assembly 28 may include any suitable features, such as knobs 30 for adjusting the car stereo system 24, or any other well known suitable features such a knob for releasing the security face plate assembly 28 from the car stereo system 24, a slot for a CD disk to pass through, an indicator for AM/FM music, a dial, etc. As further shown in FIG. 4 various embodiments of the present invention include an headphone assembly 60 which may be plugged into the security face plate assembly 28 (i.e., the built-in MP3 player/recorder 40) so a user may listen to music produced by the MP3 player/recorder 40 after the security face plate assembly 28 is removed from the car stereo system 24.

Referring now to FIG. 6 there is seen an elevational view of the security face plate assembly 28 showing exemplary control buttons for controlling and/or operating the car stereo and/or the MP3 player/recorder. By way of example only, exemplary control buttons may include audio source select knobs 100 (e.g., knob 102 for MP3 player/recorder, knob 106 for a CD player, and knob 108 for an AM/FM radio). A volume control knob 120 may be provided for controlling the volume of the car stereo 24. Exemplary control buttons may also include control knobs 130, 134 and 138. Control knob 130 may be a volume control for the MP3 built-in audio assembly. Control knob 134 may be a next/previous track, such as for both the car stereo 24 and for the MP3 built-in-audio assembly, or a next/previous preset AM/FM station on the AM/FM part of the car stereo 24. Control knob 138 may be a forward/backward control, such as a forward/backward control for both the car stereo 24 and for the MP3 built-in-audio assembly. As indicated, the security face plate assembly 28 may be removed from the car stereo system 24. Alternatively, the security face plate assembly 28 may be left in place, and a user may elected to remove only a portion of the security face plate assembly, such the part generally illustrated as 28a in FIG. 6 and containing the MP3 player/recorder 40. Thus, some of the knobs on the built-in MP3 built-in-audio assembly may be used both when the MP3 player/recorder 40 is used alone or when it is connected to the car stereo 24. The knobs may have different meaning or functions, depending on which audio source is used. It is to be understood that other knobs may exist on both the MP3 player/recorder 40 and on the car stereo 24.

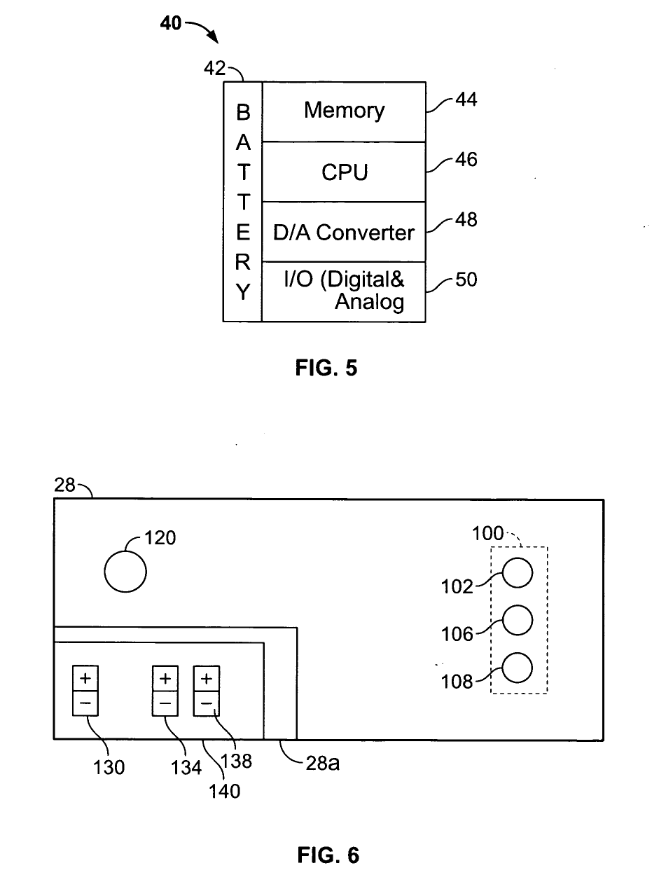

The MP3 player/recorder 40 may be any suitable MP3 player/recorder which typically includes a battery 42, memory 44 for storing musical data, a CPU 46, a D/A converter 48, and an I/O (digital & analog) section 50. FIG. 5 is a schematic diagram of an embodiment of the MP3 player/recorder 40 which is built into the security stereo face plate assembly 28.

Embodiments of the present invention allow a user to directly plug into, or couple to a car stereo (e.g., car stereo 24), the car-stereo security face plate assembly (including the built-in MP3 player), and the car stereo will continue to play over the car's loudspeaker system. Alternatively, the earphones (e.g., earphones 60) may be used in the car to listen to the music emanating from the MP3 player (e.g., MP3 player/recorder 40) included within the car-stereo security face plate assembly (e.g., assembly 20) instead of using the car's loudspeaker system. There are no cables needed for hooking-up a portable MP3 player to a car stereo system.

The MP3 player is securely fastened to the car stereo as part of the car-stereo security face plate assembly and will not float around or randomly move within the car. The music continues to play with no delay. When the user leaves the car, she/he grabs the car-stereo security face plate assembly (including the built-in MP3 player), removes it from the car stereo, plugs earphones into the stereo security face plate assembly and continues to listen to music with his/her earphones.

Thus, in practicing various embodiments of the present invention, by removing the stereo security face plate assembly having the MP3 player/recorder, the user not only secures the car stereo remaining in the car, but also allows the user to continue to listen to music while walking away from the car. The user may listen to music from the security face plate assembly either through earphones coupled to the car-stereo security face plate assembly or from a speaker built into the car-stereo security face plate assembly.

In another embodiment of the present invention the MP3 player/recorder 40 of the security face plate assembly 28 may be employed to download and record music from any suitable computer system. For this embodiment of the invention, the security face plate assembly 28 would be coupled to a suitable computer system for downloading and recording music. After the music is recorded, the music may be listened to directly from the security face plate assembly 28 (i.e., from the MP3 player/recorder 40) or over the car stereo system after the security face plate assembly 28 is coupled to the car stereo system.

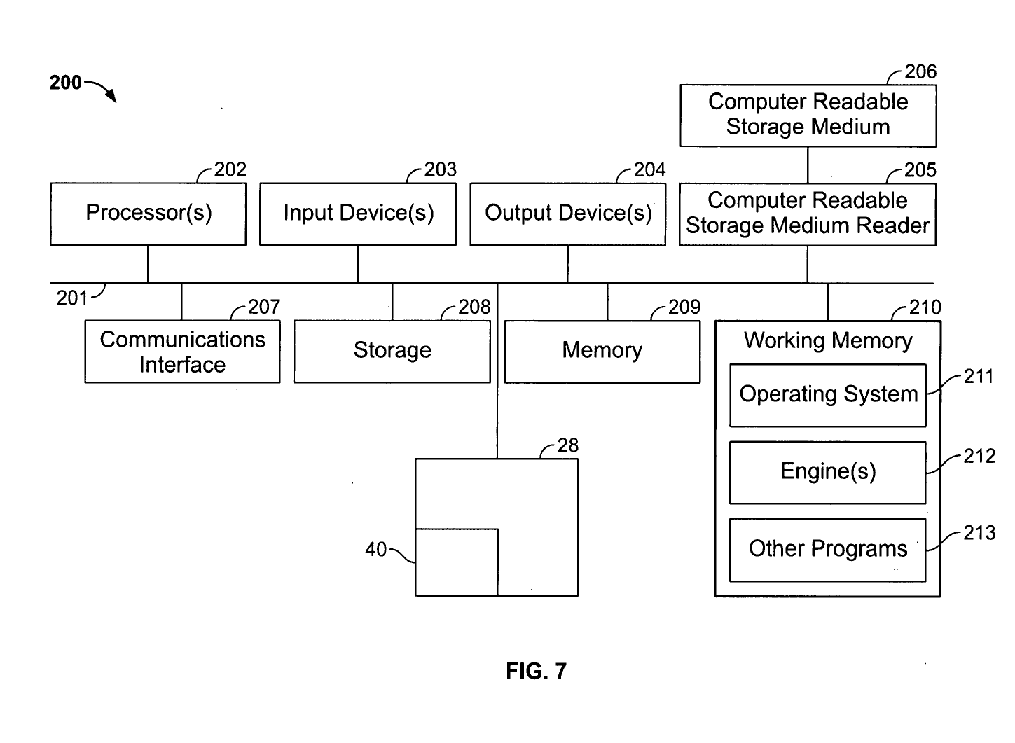

Referring in detail now to FIG. 7, there is seen, by way of illustration only, an exemplary computer system, generally illustrated as 200, to which the security face plate assembly 28 may be coupled in any suitable manner to download and record music. While other alternatives might be utilized, it will be presumed for clarity sake that control of the recording of music from the computer system 200 is implemented in hardware, software or some combination by one or more systems consistent therewith.

Computer system 200 comprises components coupled via one or more communication channels (e.g. bus 201) including one or more general or special purpose processors 202, such as a Pentium®, Centrino®, Power PC®, digital signal processor (“DSP”), and so on. Computer system 200 components also include one or more input devices 203 (such as a mouse, keyboard, microphone, pen, and so on), and one or more output devices 204, such as a suitable display, speakers, actuators, and so on, in accordance with a particular application.

Computer system 200 also includes a computer readable storage media reader 205 coupled to a computer readable storage medium 206, such as a storage/memory device or hard or removable storage/memory media. Other storage/memory device(s) are broadly illustrated separately as storage 208 and memory 209, which may include hard disk variants, floppy/compact disk variants, digital versatile disk (“DVD”) variants, smart cards, partially or fully hardened removable media, read only memory, random access memory, cache memory, and so on, in accordance with the requirements of a particular implementation. The data base(s) (i.e., the storage parameters and other data described herein or illustrated in the drawings) for identifying a substance, molecules, or the odor of a substance, may be stored in storage 208.

The computer system 200 may also further include working memory 210 and one or more suitable communication interfaces 207, such as a modem, DSL, infrared, RF or other suitable transceivers, and so on for providing inter-device communication directly or via one or more suitable private or public networks or other components that can include but are not limited to those already discussed. Coupled in any suitable manner to the communication channels (e.g. bus 201) of the computer system 200 is the security face plate assembly 28 for the downloading and recording of music by the built-in MP3 player/recorder 40.

Working memory 210 may include an operating system (“OS”) 211 which services and/or assists in adjusting and/or controlling any suitable components. The working memory 310 may also comprise an application engine 212 (e.g., an application link engine, a media device based browser, etc.) for any suitable purpose, and other programs 213. Working memory 210 components may also include a manager, one or more application programs, mobile code, data, and etc.

The particular operating system 211 may vary in accordance with a particular device, features or other aspects in accordance with a particular: application (e.g., using Windows, WindowsCE, Mac, Linux, Unix or Palm OS variants, a cell phone OS, IOS or some other proprietary OS, and so on). Various programming languages or other tools can also be utilized, such as those compatible with C variants (e.g., C++, C#), the Java 2 Platform, Enterprise Edition (“J2EE”) or other programming languages in accordance with the requirements of a particular application. Such working memory components can, for example, include one or more of applications, add-ons, applets, custom software and so on for conducting but not limited to the examples discussed elsewhere herein. Other programs 213 may, for example, include one or more of security, compression, synchronization, backup systems, groupware code, and so on, including but not limited to those discussed elsewhere herein.

When implemented in software (e.g. as an application program, object, agent, downloadable, servlet, and so on in whole or part), a document system or other component may be communicated transitionally or more persistently from local or remote storage to memory (SRAM, cache memory, etc.) for execution, or another suitable mechanism can be utilized, and elements can be implemented in compiled or interpretive form. Input, intermediate or resulting data or functional elements may further reside more transitionally or more persistently in a storage media, cache or other volatile or non-volatile memory, (e.g., storage device 208 or memory 209) in accordance with a particular application.

The MP3 player/recorder contained as part of the car-stereo security face plate assembly may have either flash memory or hard drive. If the car stereo system has a hard drive including. MP3 files that can be playing when the car-stereo security face plate assembly (including the MP3 player/recorder) is plugged in, then by practice of various embodiments of the present invention it is possible to synchronize the two units (i.e., copy files from one unit (e.g., car-stereo security face plate assembly) to the other unit (e.g., the car stereo system), if the other unit is missing the files, and vice versa). Batteries in the car-stereo security face plate assembly will be charged while plugged into the car stereo system. The car-stereo security face plate assembly (including the MP3 player/recorder) will always have suitable power from recharged batteries.

A “processor” or “process” includes any human, hardware and/or software system, mechanism or component that processes data, signals or other information. A processor may include a system with a general-purpose central processing unit, multiple processing units, dedicated circuitry for achieving functionality, or other systems. Processing need not be limited to a geographic location, or have temporal limitations. For example, a processor may perform its functions in “real time,” “offline,” in a “batch mode,” etc. Portions of processing may be performed at different times and at different locations, by different (or the same) processing systems.

Reference throughout this specification to “one embodiment”, “an embodiment”, or “a specific embodiment” means that a particular feature, structure, or characteristic described in connection with the embodiment is included in at least one embodiment of the present invention and not necessarily in all its embodiments. Therefore, the respective appearances of the phrases “in one embodiment”, “in an embodiment”, or “in a specific embodiment” in various places throughout this specification are not necessarily referring to the same embodiment. Furthermore, the particular features, structures, or characteristics of any specific embodiment of the present invention may be combined in any suitable manner with one or more other embodiments. It is to be understood that other variations and modifications of the embodiments of the present invention described and illustrated herein are possible in light of the teachings herein and are to be considered as part of the spirit and scope of the present invention.

Embodiments of the invention may be implemented by using a programmed general purpose digital computer; application specific integrated circuits; programmable logic devices; and field programmable gate arrays. In general, the functions of the present invention may be achieved by any means as is known in the art. Distributed, or networked systems, components and circuits may also be used. The communication, or transfer, of data may be wired, wireless, or by any other means.

Additionally, any signal arrows in the drawings/figures should be considered only as exemplary, and not limiting, unless otherwise specifically noted. Furthermore, the term “or” as used herein is generally intended to mean “and/or” unless otherwise indicated. Combinations of components or steps will also be considered as being noted, where terminology is foreseen as rendering the ability to separate or combine is unclear.

As used in the description herein and throughout the claims that follow, “a”, “an”, and “the” includes plural references unless the context clearly dictates otherwise. Also, as used in the description herein and throughout the claims that follow, the meaning of “in” includes “in” and “on” unless the context clearly dictates otherwise.

The foregoing description of illustrated embodiments of the present invention, including what is described in the Abstract, is not intended to be exhaustive or to limit the invention to the precise forms disclosed herein. While specific embodiments of, and examples for, the invention are described herein for illustrative purposes only, various equivalent modifications are possible within the spirit and scope of the present invention, as those skilled in the relevant art will recognize and appreciate. As indicated, these modifications may be made to the present invention in light of the foregoing description of the illustrated embodiments of the present invention and are to be included within the spirit and scope of the present invention.

Therefore, while the present invention has been described herein with reference to the particular embodiments thereof, a latitude of modification, various changes and substitutions are intended in the foregoing disclosures, and it will be appreciated that in some instances some features of the embodiments of the invention will be employed without the corresponding use of other features without departing from the scope and spirit of the invention as set forth. Therefore, many modifications may be made to adapt a particular situation or material to the essential scope and spirit of the present invention. It is intended that the invention not be limited to the particular terms used in following claims and/or to the particular embodiment disclosed as the best mode contemplated for carrying out this invention, but that the invention will include any and all embodiments and equivalents falling within the scope of the appended claims.

1. A method for listening to music comprising:
recording music by a car security face plate assembly coupled to a car stereo system;
removing the car security face plate assembly from the car stereo system; and
listening to music which was recorded by the car security face plate assembly.

2. The method for listening of claim 1 wherein said recording music comprises recording music by a car security face plate assembly having a digital audio assembly.

3. The method for listening of claim 2 additionally comprising playing, prior to said listening the music, the music by the digital audio assembly.

4. The method for listening of claim 1 wherein said listening comprises listening to the music by ear phones.

5. The method for listening of claim 1 wherein said car security face plate assembly comprises a speaker, and said listening to music comprises listening to the music from the speaker.

6. The method for listening of claim 1 wherein said car security face plate assembly comprises a power supply.

7. The method for listening of claim 6 wherein said power supply comprises a battery.

8. The method for listening of claim 7 additionally comprising charging the battery from a car battery.

9. The method for listening of claim 4 additionally comprising coupling, prior the listening to music, the ear phones to the car security face plate assembly.

10. The method for listening of claim 1 wherein said removing the car security face plate assembly provides a theft protection for the car stereo system.

11. The method of claim 3 wherein said digital audio assembly comprises an MP3 player and recorder.

12. A method for recording music comprising:
providing a car security face plate assembly having a digital audio assembly.
engaging the car security face plate assembly to a car stereo system; and
recording music after engaging the car security face plate assembly to the car stereo system.

13. The method recording of claim 12 wherein said recording music comprises recording music by the car security face plate assembly from the car stereo system.

14. The method of claim 12 wherein said recording music comprises recording music by the car stereo system from the car security face plate assembly.

15. The method for recording of claim 12 wherein said car security face plate assembly comprises a power supply.

16. The method for recording of claim 15 wherein said power supply comprises a battery.

17. The method for recording of claim 16 additionally comprising charging the battery from a car battery.

18. The method recording of claim 12 wherein said digital audio assembly comprises an MP3 player recorder.

19. A security face plate assembly for a car stereo comprising:
a security face plate having a digital audio assembly.

20. The security face plate assembly of claim 19 wherein said digital audio assembly comprises a power supply, a processor, a memory, a converter, and an input/output section.

21. A security face plate assembly comprising a security face plate having a means for processing digital audio signals.

22. The security face plate assembly of claim 21 wherein said means for processing digital audio signals comprises a player of digital audio signals.

23. The security face plate assembly of claim 21 wherein said means for processing digital audio signals comprises a recorder of digital audio signals.

24. The security face plate assembly of claim 21 wherein said means for processing digital audio signals is selected from a group of audio formats consisting of MP2, MP3, MPC, APE, FLAC, AIFF, WAV and OGG.

25. A method for recording and listening to music comprising:
providing a car security face plate assembly having a digital audio assembly.
engaging the car security face plate assembly to a computer system;
recording music from the computer system; and
listening to the music which was recorded by the car security face plate assembly from the computer system.

26. The method for recording and listening to music of claim 25 wherein said listening to music comprises engaging the car security face plate assembly to a car stereo system; and listening to the music with the car stereo system.
